(19) United States
(12) Patent Application Publication
(10) Pub. No.: US 2014/0139260 A1
(43) Pub. Date: May 22, 2014

(54) ANTI-ISLANDING FOR GRID TIED INVERTERS

(71) Applicant: SunEdison LLC, Beltsville, MD (US)

(72) Inventors: Jayaraman Vijay Shankar, San Jose, CA (US); Suryanarayana Potharaju, San Jose, CA (US)

(21) Appl. No.: 14/086,632

(22) Filed: Nov. 21, 2013

Related U.S. Application Data
(60) Provisional application No. 61/729,284, filed on Nov. 21, 2012.

(51) Int. Cl. G01R 31/40; H02M 7/42

(52) U.S. Cl. CPC G01R 31/405; H02M 7/42
USPC 324/764.01; 363/55

(57) ABSTRACT

A method of detecting an islanding condition for a grid tied inverter includes receiving a plurality of sensed operating conditions for the grid tied inverter, and determining, based on the sensed operating conditions, whether a first fault has occurred. After determining that a first fault has occurred, the method includes determining whether a second fault has occurred. An islanding fault signal is generated when the second fault is determined to have occurred.

### CROSS REFERENCE TO RELATED APPLICATIONS

This application claims priority to U.S. Provisional Patent Application Ser. No. 61/729,284, filed Nov. 21, 2012, which is hereby incorporated by reference in its entirety.

### FIELD

The field of the disclosure relates generally to grid tied inverters. More particularly, this disclosure relates to multi-pronged, redundant anti-islanding for grid tied inverters.

### BACKGROUND

Photovoltaic (PV) modules (also known as solar modules) convert solar energy into electrical energy. The electrical energy may be used directly at the site, converted for local use, and/or converted and transmitted to an electrical grid or another destination. Typically, a PV installation includes at least a plurality of PV modules logically or physically grouped together to form an array and one or more inverters that convert the direct current (DC) output of the PV modules to alternating current (AC) power.

A grid tied inverter is an inverter that feeds current to an electrical distribution grid when a grid voltage is present. When the power grid is disconnected from the inverter, a grid tied inverter must stop feeding power to the grid. Failure of the inverter to stop supplying current to the grid upon disconnection of the grid voltage, results in an electrical island, i.e. a stand-alone electrical circuit that is independent of the grid power supply. Anti-islanding capability, the ability of a grid tied inverter to avoid creation of an electrical island by discontinuing power generation upon loss of grid voltage, is generally required in grid tied inverters.

A number of conventional anti-islanding techniques for detection of grid island conditions exist. Some known systems provide anti-islanding protection through the use one or more of: power factor fault detection, over/under voltage fault detection, current fault detection frequency fault detection.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one aspect, a method of detecting an islanding condition for a grid tied inverter is described. The method includes receiving a plurality of sensed operating conditions for the grid tied inverter, and determining, based on the sensed operating conditions, whether a first fault has occurred. After determining that a first fault has occurred, the method includes determining whether a second fault has occurred. An islanding fault signal is generated when the second fault is determined to have occurred.

In another aspect, a grid tied inverter for outputting alternating current (AC) power to an electric power grid is described. The grid tied inverter includes a processor and a memory coupled to the processor. The memory includes computer-executable instructions that, when executed by the processor, cause the inverter to receive a plurality of sensed operating conditions for the grid tied inverter, determine, based on the sensed operating conditions, whether a first fault has occurred, determine, after determining that a first fault has occurred, whether a second fault has occurred, and generate an islanding fault signal when the second fault is determined to have occurred.

Yet another aspect is a computing device for controlling a grid tied inverter. The computing device includes a processor and a memory coupled to the processor. The memory includes computer-executable instructions that, when executed by the processor, cause the computing device to receive a plurality of sensed operating conditions for the grid tied inverter, determine, based on the sensed operating conditions, whether a first fault has occurred, determine, after determining that a first fault has occurred, whether a second fault has occurred, and generate an islanding fault signal when the second fault is determined to have occurred.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of an example photovoltaic (PV) module;

FIG. 2 is a cross-sectional view of the PV module shown in FIG. 1 taken along the line A-A;

FIG. 3 is a block diagram of an example computing device;

FIG. 4 is a block diagram of an example PV system;

FIG. 5 is a block diagram of a feeder line from an electric power grid coupled to provide power to a plurality of loads;

FIG. 6 is a block diagram of the feeder line from an electric power grid and an associated power generation source;

FIG. 7 is a block diagram of a system of a plurality of power islands;

FIG. 8 is a block diagram of a system of a plurality of power islands and a load island.

FIG. 9 is a functional block diagram of an example anti-islanding system;

FIG. 10 is a functional block diagram of the voltage fault detection block;

FIG. 11 is a functional block diagram of the current fault detection block;

FIG. 12 is a functional block diagram of the power factor fault detection block;

FIG. 13 is a functional block diagram of the frequency fault detection block; and

FIG. 14 is a functional block diagram of the phase lock fault detection block.

Like reference symbols in the various drawings indicate like elements.

### DETAILED DESCRIPTION

The embodiments described herein generally relate to grid tied inverters. More particularly, embodiments relate to multi-pronged, redundant anti-islanding for grid tied inverters. Still more particularly, various embodiments relate to redundant anti-islanding for grid tied inverters in photovoltaic (PV) systems.

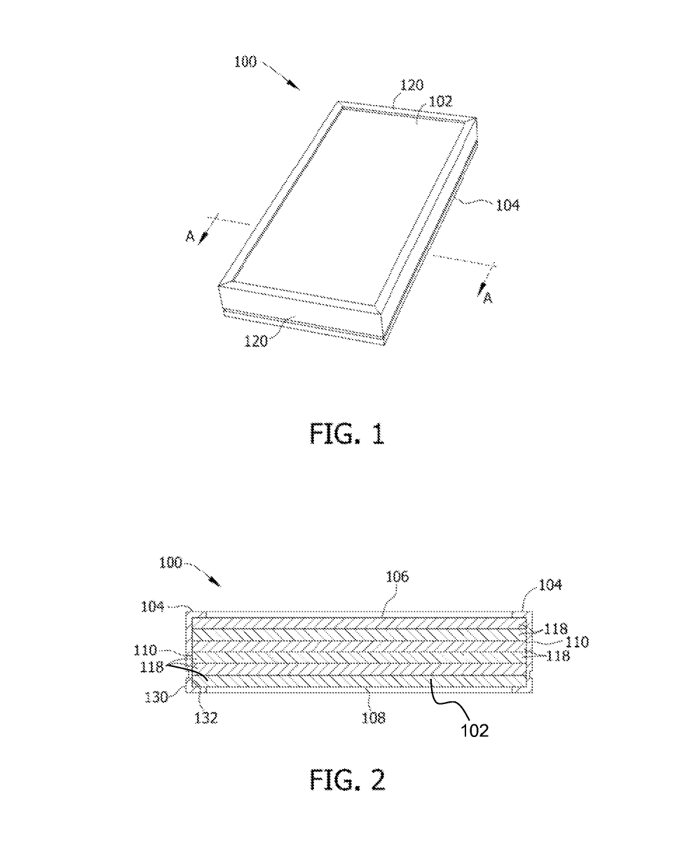

Referring initially to FIGS. 1 and 2, a PV module is indicated generally at 100. A perspective view of the PV module 100 is shown in FIG. 1. FIG. 2 is a cross sectional view of the PV module 100 taken at line A-A shown in FIG. 1. The PV module 100 includes a solar laminate 102 (also referred to as a PV laminate) and a frame 104 circumscribing the solar laminate 102.

The solar laminate 102 includes a top surface 106 and a bottom surface 108 (shown in FIG. 2). Edges 110 extend between the top surface 106 and the bottom surface 108. In this embodiment, the solar laminate 102 is rectangular shaped. In other embodiments, the solar laminate 102 may have any suitable shape.

As shown in FIG. 2, the solar laminate 102 has a laminate structure that includes several layers 118. Layers 118 may include for example glass layers, non-reflective layers, electrical connection layers, n-type silicon layers, p-type silicon layers, and/or backing layers. In other embodiments, solar laminate 102 may have more or fewer layers 118, including only one layer, or may have different layers 118, and/or may have different types of layers 118. The solar laminate 102 includes a plurality of solar cells (not shown), each of which converts solar energy to electrical energy. The outputs of the solar cells are connected in series and/or parallel to produce the desired output voltage and current for the solar laminate 102.

As shown in FIG. 1, the frame 104 circumscribes the solar laminate 102. The frame 104 is coupled to the solar laminate 102, as best seen in FIG. 2. The frame 104 assists in protecting the edges 110 of the solar laminate 102. In this embodiment, the frame 104 is constructed of four frame members 120. In other embodiments the frame 104 may include more or fewer frame members 120.

This frame 104 includes an outer surface 130 spaced apart from solar laminate 102 and an inner surface 132 adjacent solar laminate 102. The outer surface 130 is spaced apart from and substantially parallel to the inner surface 132. In this embodiment, the frame 104 is made of aluminum. More particularly, in some embodiments the frame 104 is made of 6000 series anodized aluminum. In other embodiments, the frame 104 may be made of any other suitable material providing sufficient rigidity including, for example, rolled or stamped stainless steel, plastic, or carbon fiber.

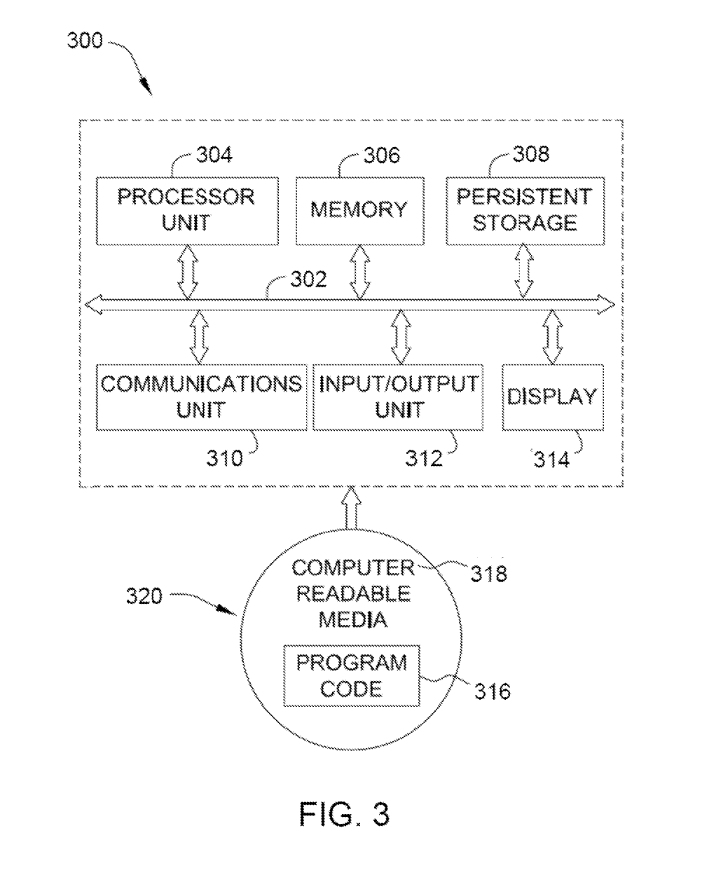

Some exemplary methods and systems are performed using and/or include computing devices. FIG. 3 is a block diagram of an exemplary computing device 300 that may be used. In the exemplary implementation, computing device 300 includes communications fabric 302 that provides communications between a processor unit 304, a memory 306, persistent storage 308, a communications unit 310, an input/output (I/O) unit 312, and a presentation interface, such as a display 314. In addition to, or in alternative to, the presentation interface may include an audio device (not shown) and/or any device capable of conveying information to a user. In some embodiments, computing device 300 is a simpler computing device 300 that does not include one or more of the components of computing device 300 described herein.

Processor unit 304 executes instructions for software that may be loaded into a storage device (e.g., memory 306). Processor unit 304 may be a set of one or more processors or may include multiple processor cores, depending on the particular implementation. Further, processor unit 304 may be implemented using one or more heterogeneous processor systems in which a main processor is present with secondary processors on a single chip. In another implementation, processor unit 304 may be a homogeneous processor system containing multiple processors of the same type. It should be understood that the terms “processor” and “processor unit” refer generally to any programmable system including systems and microcontrollers, reduced instruction set circuits (RISC), application specific integrated circuits (ASIC), programmable logic circuits, and any other circuit or processor capable of executing the functions described herein. The above examples are exemplary only, and thus are not intended to limit in any way the definition and/or meaning of the term “processor” or “processor unit.”

Memory 306 and persistent storage 308 are examples of storage devices. As used herein, a storage device is any tangible piece of hardware that is capable of storing information either on a temporary basis and/or a permanent basis. Memory 306 may be, for example, without limitation, random access memory (RAM) such as dynamic RAM (DRAM) or static RAM (SRAM), read-only memory (ROM), erasable programmable read-only memory (EPROM), electrically erasable programmable read-only memory (EEPROM), non-volatile RAM (NVRAM), and/or any other suitable volatile or non-volatile storage device. Persistent storage 308 may take various forms depending on the particular implementation, and persistent storage 308 may contain one or more components or devices. For example, persistent storage 308 may be one or more hard drives, flash memory, rewritable optical disks, rewritable magnetic tapes, and/or some combination of the above. The media used by persistent storage 308 also may be removable. For example, without limitation, a removable hard drive may be used for persistent storage 308.

A storage device, such as memory 306 and/or persistent storage 308, may be configured to store data for use with the processes described herein. For example, a storage device may store (e.g., have embodied thereon) computer-executable instructions, executable software components, PV system component data, PV system layouts, installation instructions, work orders, and/or any other information suitable for use with the methods described herein. When executed by a processor (e.g., processor unit 304), such computer-executable instructions and/or components cause the processor to perform one or more of the operations described herein.

Communications unit 310, in these examples, provides for communications with other computing devices or systems. In the exemplary implementation, communications unit 310 is a network interface card. Communications unit 310 may provide communications through the use of either or both physical and wireless communication links. Communication unit 310 provides communication to one or more element of the PV system.

Input/output unit 312 enables input and output of data with other devices that may be connected to computing device 300. For example, without limitation, input/output unit 312 may provide a connection for user input through a user input device, such as a keyboard and/or a mouse. Further, input/output unit 312 may send output to a printer. Display 314 provides a mechanism to display information, such as any information described herein, to a user. For example, a presentation interface such as display 314 may display a graphical user interface, such as those described herein. The communication device 310 may include one or more analog I/O.

Instructions for the operating system and applications or programs are located on persistent storage 308. These instructions may be loaded into memory 306 for execution by processor unit 304. The processes of the different implementations may be performed by processor unit 304 using computer implemented instructions and/or computer-executable instructions, which may be located in a memory, such as memory 306. These instructions are referred to herein as program code (e.g., object code and/or source code) that may be read and executed by a processor in processor unit 304. The program code in the different implementations may be embodied in a non-transitory form on different physical or tangible computer-readable media, such as memory 306 or persistent storage 308.

Program code 316 is located in a functional form on non-transitory computer-readable media 318 that is selectively removable and may be loaded onto or transferred to computing device 300 for execution by processor unit 304. Program code 316 and computer-readable media 318 form computer program product 320 in these examples. In one example, computer-readable media 318 may be in a tangible form, such as, for example, an optical or magnetic disc that is inserted or placed into a drive or other device that is part of persistent storage 308 for transfer onto a storage device, such as a hard drive that is part of persistent storage 308. In a tangible form, computer-readable media 318 also may take the form of a persistent storage, such as a hard drive, a thumb drive, or a flash memory that is connected to computing device 300. The tangible form of computer-readable media 318 is also referred to as computer recordable storage media. In some instances, computer-readable media 318 may not be removable.

Alternatively, program code 316 may be transferred to computing device 300 from computer-readable media 318 through a communications link to communications unit 310 and/or through a connection to input/output unit 312. The communications link and/or the connection may be physical or wireless in the illustrative examples. The computer-readable media also may take the form of non-tangible media, such as communications links or wireless transmissions containing the program code.

In some illustrative implementations, program code 316 may be downloaded over a network to persistent storage 308 from another computing device or computer system for use within computing device 300. For instance, program code stored in a computer-readable storage medium in a server computing device may be downloaded over a network from the server to computing device 300. The computing device providing program code 316 may be a server computer, a workstation, a client computer, or some other device capable of storing and transmitting program code 316.

Program code 316 may be organized into computer-executable components that are functionally related. Each component may include computer-executable instructions that, when executed by processor unit 304, cause processor unit 304 to perform one or more of the operations described herein.

The different components illustrated herein for computing device 300 are not meant to provide architectural limitations to the manner in which different implementations may be implemented. The different illustrative implementations may be implemented in a computer system including components in addition to or in place of those illustrated for computing device 300. For example, in some embodiments, computing device includes a global positioning system (GPS) receiver. Moreover, components shown in FIG. 3 can be varied from the illustrative examples shown and more or fewer components may be included. As one example, a storage device in computing device 300 is any hardware apparatus that may store data. Memory 306, persistent storage 308 and computer-readable media 318 are examples of storage devices in a tangible form.

In another example, a bus system may be used to implement communications fabric 302 and may include one or more buses, such as a system bus or an input/output bus. Of course, the bus system may be implemented using any suitable type of architecture that provides for a transfer of data between different components or devices attached to the bus system. Additionally, a communications unit may include one or more devices used to transmit and receive data, such as a modem or a network adapter. Further, a memory may be, for example, without limitation, memory 306 or a cache such as that found in an interface and memory controller hub that may be present in communications fabric 302.

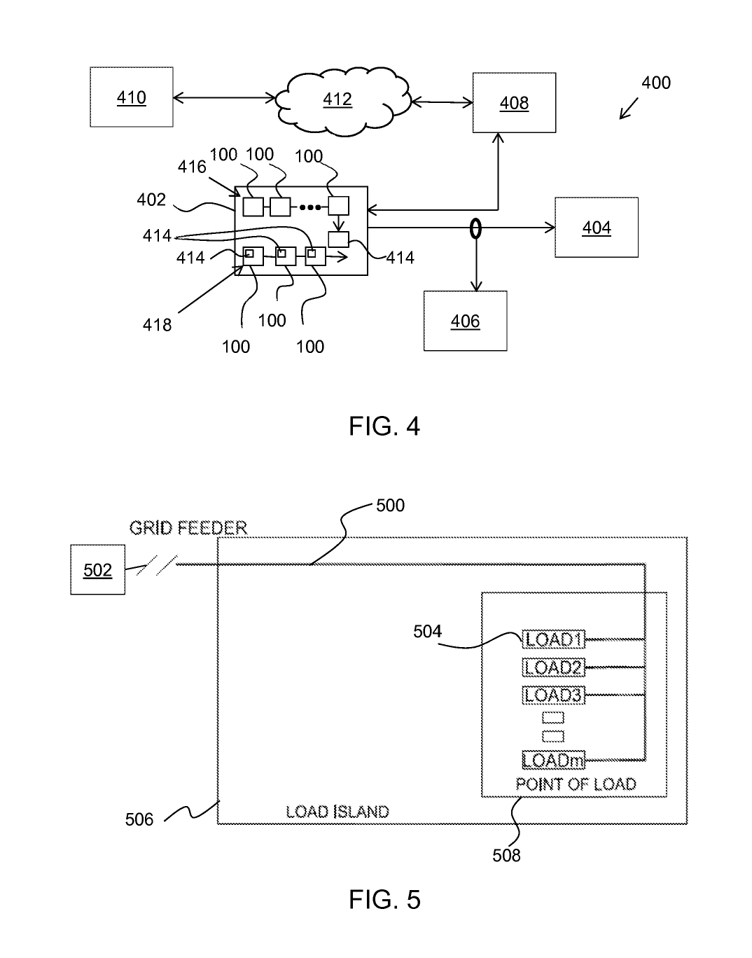

FIG. 4 is a block diagram of an exemplary PV system 400. The PV system 400 includes an array 402 of PV modules 100 and one or more inverters. The array 402 outputs AC power to one or more loads 404. In the exemplary embodiment, system 400 is a grid-tied system and load 404 is an electric distribution grid. Alternatively, loads 404 may be any other suitable loads. A meter 406 measures the power delivered to the loads 404. A gateway device 408, also referred to as a data acquisition device, a data logger, or a data acquisition system (DAS), monitors the array 402 and transmits data collected from the array 402 to a backend system 410 via a network 412. Backend system 410 includes one or more computing devices 300. Backend system 410 is usually located at a second location physically separated from the first location at which PV system 400 is located. Alternatively, the second system may be located at the same site as the PV system 400. Moreover, the gateway device 408 may provide information to and communicate with more than one backend systems 410. In some embodiments, gateway device 408 may provide anti-islanding detection for array 402.

The array 402 may be any suitable array of PV modules 100 and one or more inverters 414. For example, the array 402 may include a plurality of PV modules arranged in a string 416 of PV modules 100. Each string of modules is connected to a single inverter 414 to convert the DC output of the string of PV modules to an AC output. Alternatively, or additionally, each PV module 100 in a string 418 may be coupled to its own inverter 414 (sometimes referred to as a microinverter) positioned near or on the PV module to which it is electrically coupled. In still other examples, a plurality of strings of PV modules may be connected, directly or through one or more string combiners, to a single inverter 414, sometimes referred to as a central or string inverter. In addition to converting the DC output of modules 100 to an AC output, inverters 414 perform, for example, MPPT for one or more PV module 100. Moreover, one or more inverters 414 may provide anti-islanding protection for array 402.

In embodiments that do not include microinverters, the array 402 may include a direct current power manager (DCPM) coupled to each PV module. The DCPM performs, for example, maximum power point tracking (MPPT) for the PV module. It may also selectively control (i.e., limit and/or increase) the maximum power output of the PV module and/or control the conduction of bypass diodes based on temperature and bypass current. The DCPM may also translates the output I-V curve of the PV module to a new I-V curve at which the output voltage does not vary with ambient temperature.

In some embodiments, the array 402 includes one or more tracking devices configured to selectively position the PV modules relative to the sun to attempt to maximize the solar energy incident on the PV modules over time. Any other suitable arrangement of PV modules and inverter(s) may be used, including combinations of the arrangements described above.

The gateway device 408 collects data concerning array 402, such as via one or more sensors (not shown). The gateway device 408 is and/or includes a computing device, such as computing device 300. The collected data may include any appropriate operational, situational, environmental, or other data related to the operation and/or condition of the array 402. For example, the gateway may monitor the ambient air temperature around the array 402, the amount of sunlight incident on the array 402 (or one or more PV module), the output voltage and current of the array 402, the output voltage and current of each PV module, the output voltage and current of each inverter and/or microinverter 414, the surface temperature of the PV modules 100, etc. Moreover, in some embodiments, the gateway device 408 is in communication with one or more components of the array 402. For example, the gateway device 408 may be in communication with one or more inverters 414 in the array 402. Each inverter 414 may provide the gateway device 408 with, for example, its input voltage, its input current, its output voltage, its output current, etc. In some embodiments, the array 402 (and more particularly the inverters 414) may be controlled via the gateway device 408.

In one example, the network 412 is the Internet. In other implementations, network 412 is any other suitable communication network, including, for example, a wide area network (WAN), a local area network (LAN), a cellular network, etc. Network 412 may include more than one network. For example, gateway device 408 may connect to the Internet through one or more other networks and/or interfaces, such as a local area network (LAN), a wide area network (WAN), a home area network (HAN), dial-in-connections, cable modems, and high-speed ISDN lines.

In some embodiments, system 400 includes at least one local or remotely located system controller (not shown). The system controller may be responsible for monitoring and coordinating operation of the inverters 414, solar trackers, etc. Moreover, the system controller may monitor and provide anti-islanding protection for array 402 and inverters 414.

FIG. 5 is a block diagram of a feeder line 500 from an electric power grid 502 coupled to provide power to a plurality of loads 504. The loaded power grid shown in FIG. 5 may sometimes be referred to as a load island 506.

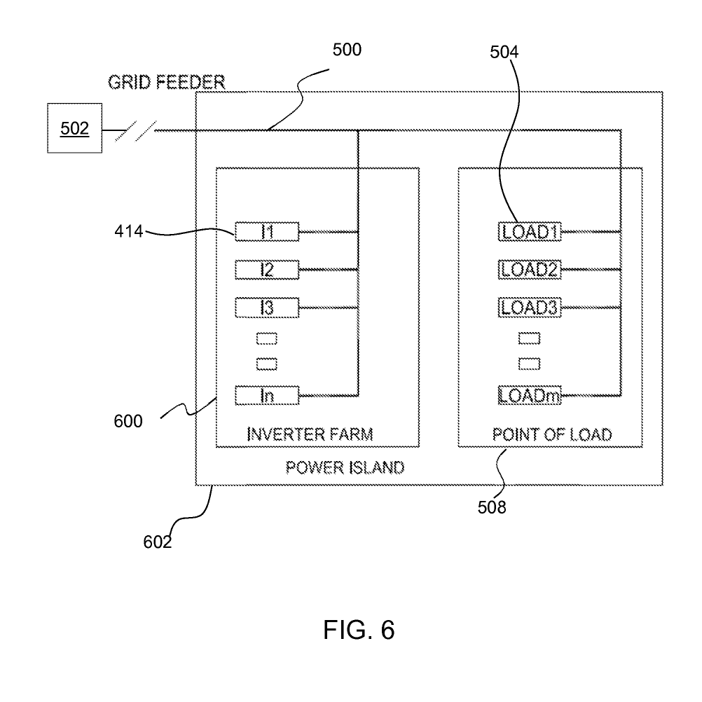

FIG. 6 is a block diagram of the feeder line 500 from electric power grid 502 and an associated power generation source 600. Power grid 502 and source 600 provide power to the loads 504. The plurality of loads 504 form a load 508 (also referred to as a point of load 508). In an exemplary embodiment, the power generation source is a PV system, such as system 400, including a plurality of grid tied inverters 414. The configuration shown in FIG. 6 is sometimes referred to as a power island 602.

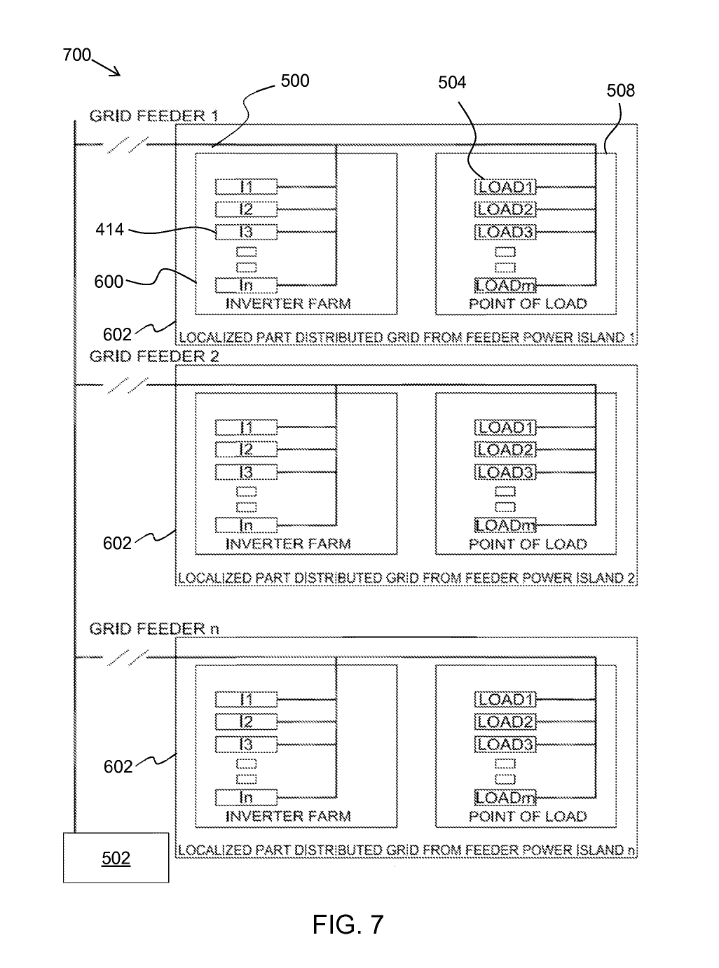

FIG. 7 is a block diagram of a system 700 of a plurality of power islands 602. Feeder lines 500 from electric power grid 502 are connected to a plurality of associated power generation sources 600. Power grid 502 and sources 600 provide power to the loads 502. In an exemplary embodiment, the power generation source is a PV system, such as system 400, including a plurality of grid tied inverters 414.

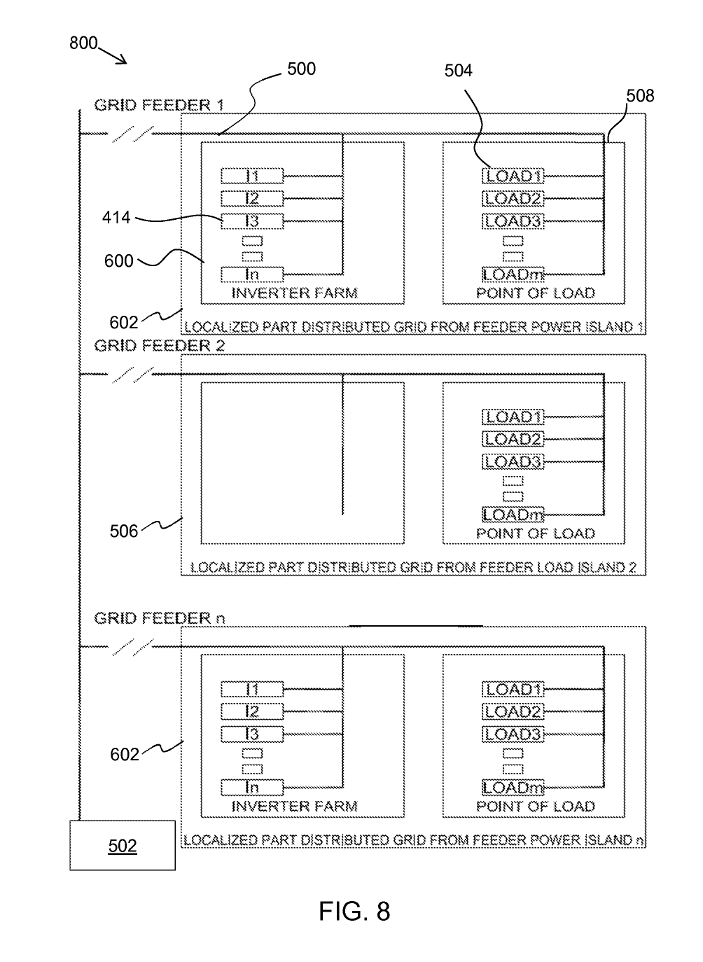

FIG. 8 is a block diagram of a system 800 of a plurality of power islands 602 and a load island 506. Feeder lines 500 from electric power grid 502 are connected to a plurality of associated power generation sources 600. Power grid 502 and sources 600 provide power to the loads 502. In an exemplary embodiment, the power generation source is a PV system, such as system 400, including a plurality of grid tied inverters 414.

With reference to FIGS. 5-8, Grid feeder 500 is sometimes disconnected from grid 502, such as to ensure the safety of power line maintenance workers when the grid is being maintained and/or repaired. Moreover, sometimes a feeder 500 is unintentionally disconnected from grid 502, such as due to physical damage to one or more power lines of the grid 502, a damaged transformer, or the like. For the system shown FIG. 5, disconnection of the feeder 500 from the grid 502 always disconnects the load island 506 and loads 504 from power. For the systems shown in FIGS. 6, 7, and 8, one or more loads 504 may continue to receive power from sources 600 after feeder(s) 500 are disconnected from the grid 502 (i.e., one or more loads 504 may form power islands that are energized and receiving power when the surrounding systems and portions of the grid are de-energized).

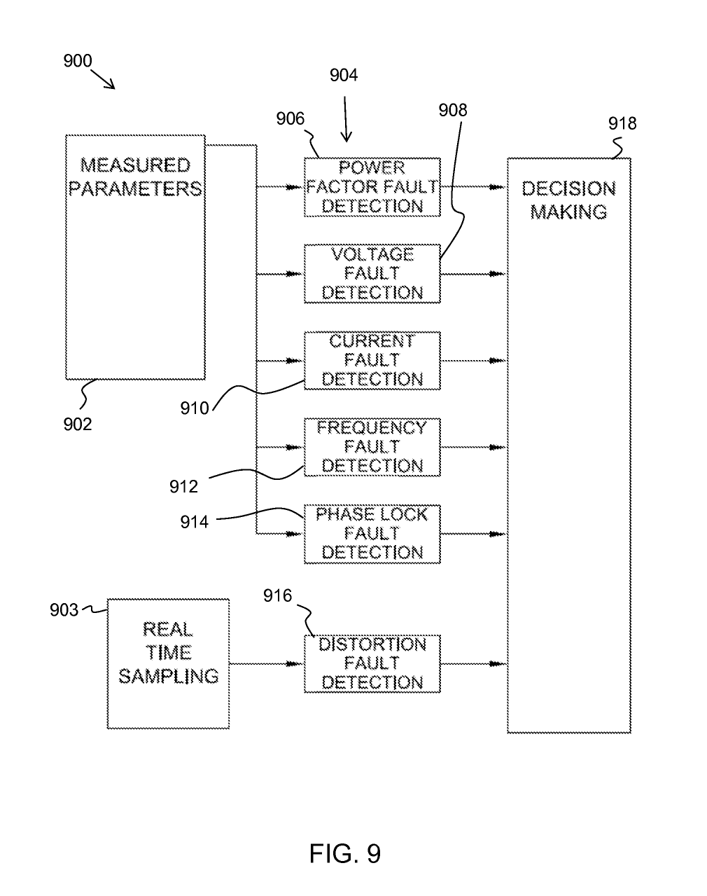

FIG. 9 is a functional block diagram of an example anti-islanding system 900 for use in connection with, for example, sources 600. More particularly, system 900 may be included in PV system 400. In some embodiments, anti-islanding system 900 is incorporated in one or more inverters 414. Anti-islanding system 900 is a redundant anti-islanding system to determine the grid anti-islanding criteria to approach a one hundred percent probability of anti-islanding. For simplicity of description, anti-islanding system 900 will be described with reference to PV system 400, an inverter 414, and grid 502. In other embodiments, system 900 may be incorporated in other grid-tied systems and/or in different component(s) of PV system 400. Moreover, anti-islanding system 900 may be embodied in more than one component (e.g., some functions of system 900 may be performed by an inverter 414, while other functions are performed by a central controller).

Measured parameters 902 and real time samples 903 are received by system 900. The measured parameters 902 are any suitable parameters of PV system 400 and/or grid 502. For example, measured parameters may include a grid voltage, a current output of the inverter 414, an operating frequency of the inverter.

Measured parameters 902 and real time samples 903 are supplied to six detection blocks 904. The detection blocks include a power fault detection block 906, a voltage fault detection block 908, a current fault detection block 910, a frequency fault detection block 912, and a phase lock fault detection block 914. Real time samples 903 are provided to a distortion fault detection block 916. The outputs of detection blocks 904 are provided to decision making block 918 for detection of potential islanding and a determination to institute anti-islanding protections.

There are six conditions that may exist in systems, such as the systems shown in FIGS. 5-8, when islanding may be occurring. The first condition is the power generated by the inverter(s) is greater than the power consumed by the load at a unity power factor. The second condition occurs when the power generated by the inverter(s) is less than the power consumed by the load at unity power factor. In the third condition, the power generated by the inverter(s) equals the power consumed by the load at unity power factor. The fourth load occurs when the power generated by the inverter(s) is greater than the power consumed by load at a non-unity power factor. In the fifth condition, the power generated by inverter(s) is less than the power consumed by the load at a non-unity power factor. The sixth condition occurs when the power generated by the inverter(s) equals the power consumed by the load at a non-unity power factor.

The third condition is not achievable in a system using a plurality of inverters and loads as this condition is abstract and self-locking. This condition does not provide disturbance on the grid needed by some prior anti-islanding methods to detect the island condition.

Referring again to FIG. 9, the detection blocks 904 generally work on the alternating current system electrical phenomenon which is described by the equation:

Power=Voltage×Current×Power Factor (1)

The grid tied inverter 414 is specified to run under a certain grid voltage conditions, specified by a minimum grid voltage (Vmin), an operating grid voltage (Vop), and a maximum grid voltage, (Vmax). The grid voltage conditions satisfy the mathematical relation:

Vmin<Vop<Vmax (2)

The grid tied inverter 414 is specified to operate under a certain output current, specified by a maximum current that can be generated (Imax) and a generated current (Iop). The current conditions satisfy the mathematical condition:

Iop<Imax (3)

The grid tied inverter 414 is also specified to operate within a certain minimum power factor (Pfmin) and output power factor (Pfop), satisfying the mathematical condition:

Pfop>Pfmin (4)

Applying the specified operating conditions to equation (1), under operating conditions equation (1) becomes:

Power=Vop*lop*Pfop (5)

The operating grid frequency for the grid tied inverter is limited by the bounds:

Fmin<Fop<Fmax (6)

where Fmin, Fop, Fmax are minimum, operating, and maximum frequencies respectively.

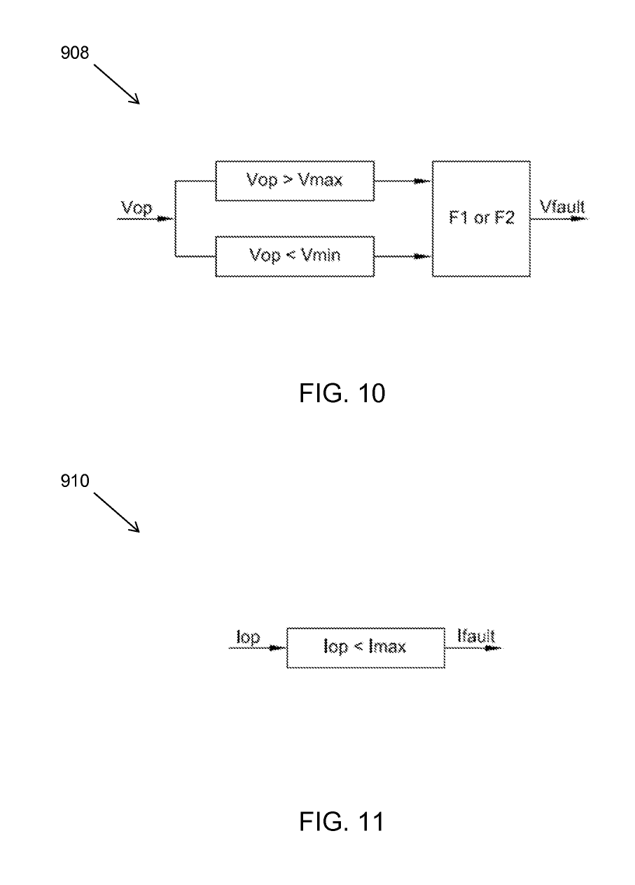

FIG. 10 is a functional block diagram of the voltage fault detection block 908. The voltage fault detection block 908 detects islanding conditions arising due to the first and second conditions described above. When power is generated by the inverter 414, the first condition causes the operating voltage Vop to decrease below Vmin. The second condition causes the operating voltage Vop to increase beyond Vmax. The voltage fault detection block 908 confirms that Vop satisfies the condition Vmin<Vop<Vmax, failing which a fault signal (Vfault) is generated.

FIG. 11 is a functional block diagram of the current fault detection block 910. The current fault detection block 910 detects anti-islanding conditions arising due to the second and fifth conditions specified above. When power is generated by the inverter 414, the second condition and the fifth condition cause the generated current Iop of the inverter 414 to increase beyond Imax. The current fault detection block 910 looks for Iop to satisfy the condition Iop<Imax, failing which a fault signal (Ifault) is generated.

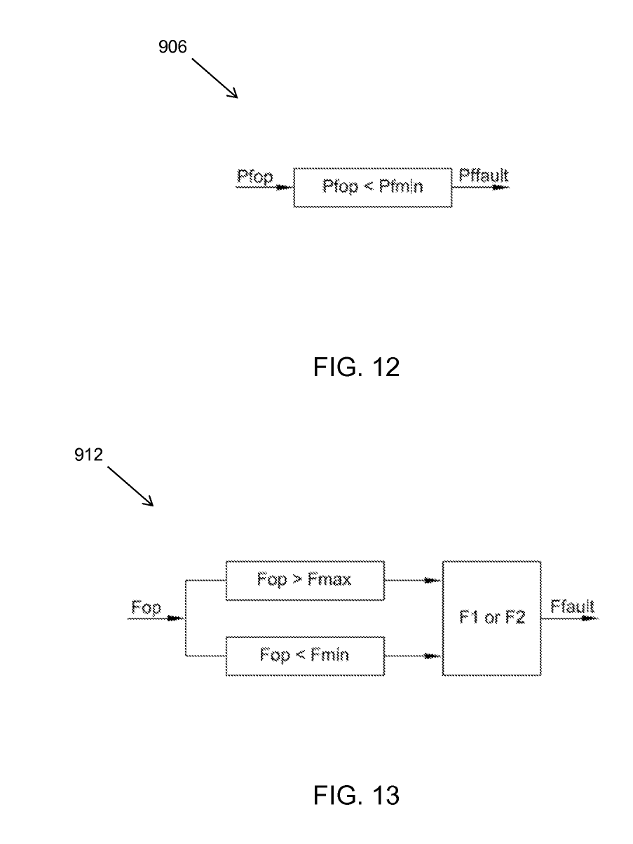

FIG. 12 is a functional block diagram of the power factor fault detection block 906. The power factor fault detection block 906 detects anti-islanding conditions arising from the fourth and fifth conditions specified above. When power is generated by the inverter 414, the fourth and fifth conditions cause the output power factor Pfop to decrease below the minimum power factor Pfmin. The power factor fault detection block 906 determines if Pfop satisfies the condition Pfop<Pfmin, failing which a fault signal (Pffault) is generated.

FIG. 13 is a functional block diagram of the frequency fault detection block 912. The frequency fault detection block 912 detects anti-islanding conditions arising due to the first, second, fourth, and fifth conditions specified above. When power is generated by the inverter 414, the first, second, fourth, and fifth conditions cause the operating frequency Fop of the inverter 414 to fall below Fmin or increase beyond Fmax. The frequency fault detection block 912 checks that the operating frequency Fop satisfies the condition Fmin<Fop<Fmax, failing which a fault signal Ffault is generated.

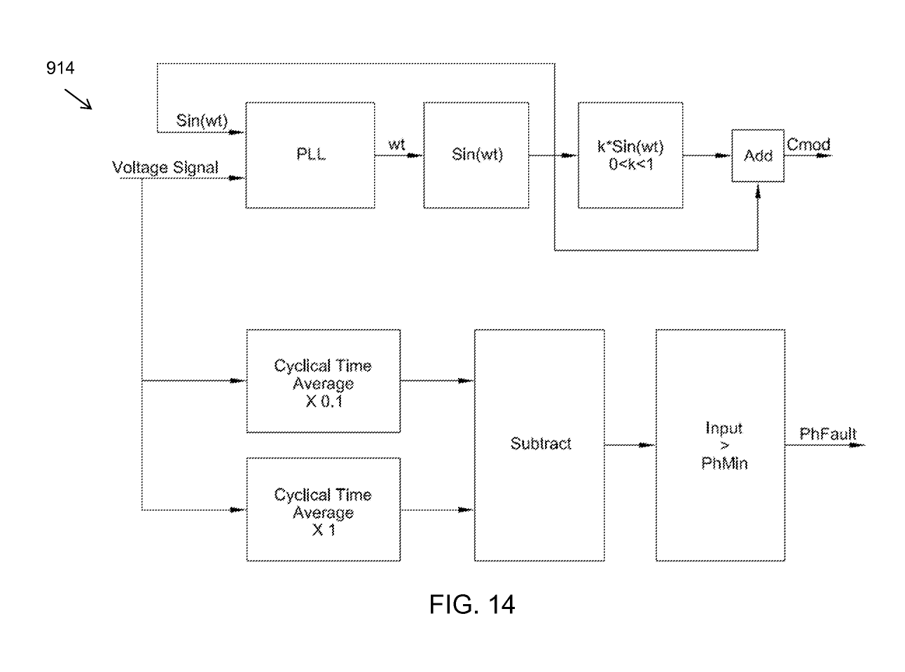

FIG. 14 is a functional block diagram of the phase lock fault detection block 914 and distortion fault detection block 916. The phase lock fault detection block 914 detects anti-islanding conditions arising from the all six of the conditions specified above. Generally, all of the specified conditions will cause the Phase-Locked Loop (PLL) to jitter. Phase lock fault detection block 914 detects the jitter to detect potential islanding.

In further detail, inverter 414 generally includes one PLL for each output phase of the inverter 414. The PLL is meant to match and maintain the phase of the output of the inverter 414 with the phase of the grid voltage. The PLL introduces a small distortion into the output current waveform, by altering the modulation of the output current (Cmod), to make it distinct with respect to the grid voltage waveform without compromising the zero crossing and the power factor of the inverter 414. This phase jitter distortion is absent in the grid system when the grid voltage is present, but detectable by distortion fault detection block 916 when the grid voltage is not present. Under islanding conditions, the voltage waveform matches with the current waveform. The phase lock fault detection block 914 employs a predetermined minimum threshold value of PhMin that is greater than the measured phase PhMeasured when the grid is present. In the absence of the grid, PhMeasured is always greater than PhMin. The phase lock fault detection block 914 detects when PhMeasured is greater than PhMin and generates a fault signal (PhFault).

In the example embodiment, when the decision making block 918 receives a fault signal (e.g., Vfault, Ifault, Pffault, Ffault, or PhFault) from one of the detection blocks 904, the decision making block 918 checks for other faults to ascertain that a power island has occurred. The decision making block 918 also initiates a redundancy check when a fault signal is received. To ascertain the islanding condition in the redundancy check, a phase variation is created to accelerate the PhFault occurrence. The phase variation is a modulated wave on the inverter output voltage. In the presence of the grid voltage, the modulated wave does not trigger a PhFault. When the grid voltage is not present, the modulated wave oscillates rapidly to create a PhFault. This additional redundancy in fault mechanism prevents unintentional islanding and simultaneously ensures that all real island conditions are detected with certainty. In other embodiments, the decision making block 918 determines that an islanding condition exists when fault signals are received from any two detection blocks 904.

A technical effect of the method, device, and system described herein may include one or more of: (a) receiving a plurality of sensed operating conditions for the grid tied inverter; (b) determining, based on the sensed operating conditions, whether a first fault has occurred; (c) determining, after determining that a first fault has occurred, whether a second fault has occurred; and (d) generating an islanding fault signal when the second fault is determined to have occurred.

The methods and systems of the present disclosure provide effective and accurate islanding detection and anti-islanding triggering for grid tied inverters. The example embodiments are applicable to all power islanding conditions in systems with one or a plurality of grid tied inverters connected to one or a plurality of phases of an electric power grid. The example embodiments provide an effective way to detect all islanding conditions and effectively trigger anti-islanding to shut down power generation of the grid tied inverter. Example embodiments incorporate multiple anti-islanding detection capabilities for various fault conditions, while eliminating the failure modes of some known techniques. Redundant fault detection for islanding effects that impact inverter phase-locking function is incorporated, thereby providing an effective mechanism for detection of islanding under substantially all possible conditions. An advantage of embodiments of the present disclosure is that islanding is detected and anti-islanding is effectively triggered with probability of 1.0 or 100% in all power islanding conditions in a singularity or plurality of grid tied inverters connected in a singularity or plurality of phases connected to the power grid. Embodiments of the disclosed systems are capable of detecting all islanding conditions and effectively trigger anti-islanding and shutoff of power generation by the grid tied inverter.

This written description uses examples to disclose various embodiments, which include the best mode, to enable any person skilled in the art to practice those embodiments, including making and using any devices or systems and performing any incorporated methods. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A method of detecting an islanding condition for a grid tied inverter, the method comprising:
receiving a plurality of sensed operating conditions for the grid tied inverter;
determining, based on the sensed operating conditions, whether a first fault has occurred;
determining, after determining that a first fault has occurred, whether a second fault has occurred; and
generating an islanding fault signal when the second fault is determined to have occurred.

2. The method of claim 1, wherein determining whether a first fault has occurred comprises determining whether a first fault of a plurality of potential faults has occurred.

3. The method of claim 2, wherein the plurality of potential faults comprises at least two of an overvoltage fault, an undervoltage fault, an overcurrent fault, a power factor fault, an overfrequency fault, an underfrequency fault, and a phase fault.

4. The method of claim 2, wherein determining whether a second fault has occurred comprises determining whether a second fault of the plurality of potential faults has occurred.

5. The method of claim 1, wherein determining whether a second fault has occurred comprises determining whether a phase fault has occurred.

6. The method of claim 5, wherein determining whether a phase fault has occurred comprises adding a phase variation to an output voltage of the grid tied inverter.

7. The method of claim 1, wherein the plurality of sensed operating conditions comprise at least two of an output voltage of the grid tied inverter, an output current of the grid tied inverter, a power factor of the output of the grid tied inverter, and an operating frequency of the grid tied inverter.

8. A grid tied inverter for outputting alternating current (AC) power to an electric power grid, the grid tied inverter comprising a processor and a memory coupled to the processor, wherein the memory comprises computer-executable instructions that, when executed by the processor, cause the inverter to:
receive a plurality of sensed operating conditions for the grid tied inverter;
determine, based on the sensed operating conditions, whether a first fault has occurred;
determine, after determining that a first fault has occurred, whether a second fault has occurred; and
generate an islanding fault signal when the second fault is determined to have occurred.

9. The grid tied inverter of claim 8, wherein the memory further comprises computer-executable instructions that, when executed by the processor, cause the grid tied inverter to determine whether a first fault has occurred by determining whether a first fault of a plurality of potential faults has occurred.

10. The grid tied inverter of claim 9, wherein the plurality of potential faults comprises at least two of an overvoltage fault, an undervoltage fault, an overcurrent fault, a power factor fault, an overfrequency fault, an underfrequency fault, and a phase fault.

11. The grid tied inverter of claim 9, wherein the memory further comprises computer-executable instructions that, when executed by the processor, cause the grid tied inverter to determine whether a second fault has occurred by determining whether a second fault of the plurality of potential faults has occurred.

12. The grid tied inverter of claim 8, wherein the memory further comprises computer-executable instructions that, when executed by the processor, cause the grid tied inverter to determine whether a second fault has occurred by determining whether a phase fault has occurred.

13. The grid tied inverter of claim 12, wherein the memory further comprises computer-executable instructions that, when executed by the processor, cause the grid tied inverter to determine whether a phase fault has occurred by adding a phase variation to an output voltage of the grid tied inverter.

14. The grid tied inverter of claim 8, wherein the plurality of detected operating conditions comprise at least two of an output voltage of the grid tied inverter, an output current of the grid tied inverter, a power factor of the output of the grid tied inverter, and an operating frequency of the grid tied inverter.

15. The grid tied inverter of claim 8, wherein the memory further comprises computer-executable instructions that, when executed by the processor, cause the grid tied inverter to stop outputting AC power to the electric power grid in response to the islanding fault signal.

16. A computing device for controlling a grid tied inverter, the computing device comprising a processor and a memory coupled to the processor, wherein the memory comprises computer-executable instructions that, when executed by the processor, cause the computing device to:
receive a plurality of sensed operating conditions for the grid tied inverter;
determine, based on the sensed operating conditions, whether a first fault has occurred;
determine, after determining that a first fault has occurred, whether a second fault has occurred; and
generate an islanding fault signal when the second fault is determined to have occurred.

17. The computing device of claim 16, wherein the memory further comprises computer-executable instructions that, when executed by the processor, cause the computing device to determine whether a first fault has occurred by determining whether a first fault of a plurality of potential faults has occurred.

18. The computing device of claim 17, wherein the memory further comprises computer-executable instructions that, when executed by the processor, cause the computing device to determine whether a second fault has occurred by determining whether a second fault of the plurality of potential faults has occurred.

19. The computing device of claim 16, wherein the memory further comprises computer-executable instructions that, when executed by the processor, cause the computing device to determine whether a second fault has occurred by determining whether a phase fault has occurred.

20. The computing device of claim 19, wherein the memory further comprises computer-executable instructions that, when executed by the processor, cause the computing device to determine whether a phase fault has occurred by adding a phase variation to an output voltage of the grid tied inverter.
